(19) United States
(12) Patent Application Publication
(10) Pub. No.: US 2014/0043051 A1
(43) Pub. Date: Feb. 13, 2014

(54) INSPECTION APPARATUS, INSPECTION SYSTEM AND INSPECTION METHOD

(71) Applicant: TOKYO ELECTRON LIMITED, Minato-ku (JP)

(72) Inventors: Haruo IWATSU, Koshi City (JP); Yoshinori FUJISAWA, Fuchu City (JP)

(73) Assignee: TOKYO ELECTRON LIMITED, Minato-ku (JP)

(21) Appl. No.: 14/051,582

(22) Filed: Oct. 11, 2013

Related U.S. Application Data
(63) Continuation of application No. PCT/JP2012/059882, filed on Apr. 11, 2012.

(30) Foreign Application Priority Data
Apr. 12, 2011 (JP) 2011-087923

(51) Int. Cl. G01R 31/319

(52) U.S. Cl. CPC G01R 31/31919
USPC 324/750.01

(57) ABSTRACT

An inspection apparatus for inspecting target objects includes multiple inspection cells corresponding to target objects, respectively, and a test-pattern wiring formed between the inspection cells. Each of the inspection cell includes a test pattern memory device which temporarily stores a test pattern, an inspection signal driver device which transmits an inspection signal to a respective one of the target objects based on the test pattern, a comparator device which compares an output signal from the respective one of the target objects with an expected value corresponding to the test pattern such that a test result is obtained, and a test result memory device which temporarily stores the test result, and the test-pattern wiring transmits the test pattern to the test pattern memory device of each of the inspection cells from an upstream side to a downstream side in the order that the target objects are inspected.

### CROSS-REFERENCE TO RELATED APPLICATIONS

The present application is a continuation of PCT/JP2012/059882, filed Apr. 11, 2012, which is based upon and claims the benefit of priority to Japanese Application No. 2011-087923, filed Apr. 12, 2011. The entire contents of these applications are incorporated herein by reference.

### BACKGROUND OF THE INVENTION

1. Field of the Invention

A technology disclosed in the present application relates to an inspection apparatus, an inspection system and an inspection method for inspection of multiple target objects.

2. Description of Background Art

Electrical characteristics of devices formed on, for example, a semiconductor wafer (hereinafter, referred to as a “wafer”) are inspected using, for example, a tester and a probe card attached to a probe apparatus. In general, the probe card includes multiple probes, contactors that support the probes, and a circuit board that transmits inspection signals to the probes. Further, the tester includes a driver for transmitting an inspection signal to the probe card and a comparator for comparing an output signal from the probe card with an expected value.

In such a case, the electrical characteristics of the devices are inspected by bringing the multiple probes into contact with electrodes of the devices formed on the wafer and transmitting the inspection signals to the devices on the wafer through the circuit board, the contactors and the probes from the driver of the tester. Furthermore, the output signal is transmitted from the devices to the comparator of the tester through the probe, the contactor and the circuit board. Moreover, the electrical characteristics of the devices are inspected by using the comparator to compare the output signal with the expected value.

When the driver and the comparator are provided in the tester, since the length of a wiring that connects the tester and the probe card is increased, there is a concern that resistance of the wiring is increased or transmission delay is increased. In addition, since a signal is not appropriately transmitted between the tester and the probe card, the inspection accuracy of the device is degraded and the inspection speed is decreased.

JP 1-235345 A suggests a technology of disposing a comparator to be adjacent to the device serving as a target object instead of positioning it in a tester as is conventionally done. The entire contents of this publication are incorporated herein by reference.

### SUMMARY OF THE INVENTION

According to one aspect of the present invention, an inspection apparatus for inspecting target objects includes multiple inspection cells corresponding to target objects, respectively, and a test-pattern wiring formed between the inspection cells. Each of the inspection cell includes a test pattern memory device which temporarily stores a test pattern, an inspection signal driver device which transmits an inspection signal to a respective one of the target objects based on the test pattern, a comparator device which compares an output signal from the respective one of the target objects with an expected value corresponding to the test pattern such that a test result is obtained, and a test result memory device which temporarily stores the test result, and the test-pattern wiring transmits the test pattern to the test pattern memory device of each of the inspection cells from an upstream side to a downstream side in the order that the target objects are inspected.

According to another aspect of the present invention, an inspection system for inspecting target objects includes an inspection apparatus which inspects multiple target objects, a control device which controls inspection of the target objects by the inspection apparatus, and a tester device which transmits a test pattern to the inspection apparatus and receives a test result from the inspection apparatus. The inspection apparatus includes multiple inspection cells corresponding to the target objects, respectively, and a test-pattern wiring formed between the inspection cells, each of the inspection cells includes a test pattern memory device which temporarily stores the test pattern, an inspection signal driver device which transmits an inspection signal to a respective one of the target objects based on the test pattern, a comparator device which compares an output signal from the respective one of the target objects with an expected value corresponding to the test pattern such that a test result is obtained, and a test result memory device which temporarily stores the test result, the test-pattern wiring transmits the test pattern to the test pattern memory device of each of the inspection cells from an upstream side to a downstream side in the order that the target objects are inspected, and the tester device transmits the test pattern to the test pattern memory device and receives the test result from the test result memory device.

According to yet another aspect of the present invention, an inspection method for inspecting target objects includes temporarily storing a test pattern in a test pattern memory device, transmitting an inspection signal to a target object from an inspection signal driver device based on the test pattern, comparing an output signal from the target object with an expected value corresponding to the test pattern by a comparator device such that a test result is obtained, and temporarily storing the test result in a test result memory device. The test pattern memory device, the inspection signal driver device, the comparator device, and the test result memory device are formed in each of inspection cells corresponding to target objects, respectively, and the test pattern stored in the test pattern memory device of each of the inspection cells is sequentially transmitted to the test pattern memory device of another one of the inspection cells on a downstream side such that the inspection cells sequentially inspect the target objects based on the test pattern transmitted.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 is an explanatory diagram schematically illustrating the structure of an inspection system according to an embodiment;

FIG. 2 is an explanatory diagram schematically illustrating the structure of the inspection system;

FIG. 3 is an explanatory diagram illustrating timings for inspection of multiple devices in the inspection system;

FIG. 4 is an explanatory diagram schematically illustrating the structure of an inspection system according to another embodiment;

FIG. 5 is an explanatory diagram schematically illustrating the structure of an inspection system according to yet another embodiment;

FIG. 6 is an explanatory diagram illustrating timings for inspection of multiple devices in the inspection system according to the another embodiment;

FIG. 7 is an explanatory diagram schematically illustrating the structure of an inspection system according to yet another embodiment;

FIG. 8 is an explanatory diagram illustrating timings for inspection of multiple devices in the inspection system according to yet another embodiment;

FIG. 9 is an explanatory diagram schematically illustrating the structure of an inspection system according to yet another embodiment;

FIG. 10 is an explanatory diagram schematically illustrating the structure of an inspection system according to yet another embodiment;

FIG. 11 is an explanatory diagram schematically illustrating the structure of an inspection apparatus according to yet another embodiment;

FIG. 12 is an explanatory diagram schematically illustrating the structure of an inspection apparatus according to yet another embodiment;

FIG. 13 is an explanatory diagram schematically illustrating the structure of an inspection system according to yet another embodiment; and

FIG. 14 is an explanatory diagram schematically illustrating the structure of an inspection system according to yet another embodiment.

### DETAILED DESCRIPTION OF THE EMBODIMENTS

The embodiments will now be described with reference to the accompanying drawings, wherein like reference numerals designate corresponding or identical elements throughout the various drawings.

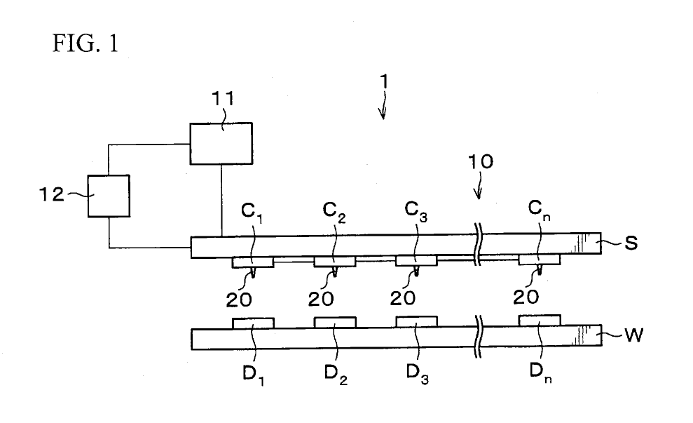

FIG. 1 is an explanatory diagram illustrating a structure of an inspection system 1 according to an embodiment. The inspection system 1 inspects multiple devices (D), serving as target objects, which are formed on a wafer (W). In the embodiment, a case where a function test for the inspection of dynamic characteristics of the devices (D)—for example, operations or operating speeds of the devices (D)—is performed as the inspection of the devices (D) will be described.

For example, as illustrated in FIG. 1, the inspection system 1 includes an inspection apparatus 10 and a tester 11. The tester 11 transmits a test pattern to the inspection apparatus 10 and receives a test result from the inspection apparatus 10. Further, in order to control, for example, the inspection of the multiple devices (D), the inspection system 1 includes a control unit 12 that controls the inspection apparatus 10 and the tester 11. Although not illustrated, the inspection system 1 also includes a chuck for adsorbing and holding the wafer (W) and a moving mechanism that moves the chuck in a vertical direction and a horizontal direction.

The inspection apparatus 10 includes multiple inspection cells (C). The multiple inspection cells (C) are supported by, for example, a support substrate (S). The support substrate (S) is made from, for example, the same material as that of the wafer (W), and has the same planar shape as that of the wafer (W). Probes 20 which come in contact with electrodes of the devices (D) are formed respectively at the inspection cells (C). That is, the inspection cells (C) and the probes 20 are formed in one-to-one correspondence. The material and shape of the support substrate (S) are not limited to those of the present embodiment, and various materials and shapes may be used as long as a substrate can support the multiple inspection cells (C).

The multiple inspection cells (C) are provided so as to correspond respectively to the multiple devices (D) on the wafer (W). In the present embodiment, for the sake of convenience in description, the inspection apparatus 10 includes n sets of inspection cells (C) (where n is an integer of 2 or greater), and the inspection cells (C) are respectively referred to as a first inspection cell (C₁) to an n-th inspection cell (Dₙ). Similarly, the devices (D) formed on the wafer (W) are also referred respectively to as a first device (D₁) to an n-th device (Dₙ). The first inspection cell (C₁) to the n-th inspection cell (Cₙ) and the first device (D₁) to the n-th device (Dₙ) are formed in one-to-one correspondence. Further, in the present embodiment, the first device (D₁) to the n-th device (Dₙ) are sequentially inspected by the first inspection cell (C₁) to the n-th inspection cell (Cₙ). The multiple devices (D) on the wafer (W) and the multiple inspection cells (C) of the inspection apparatus 10 may be arbitrarily arranged.

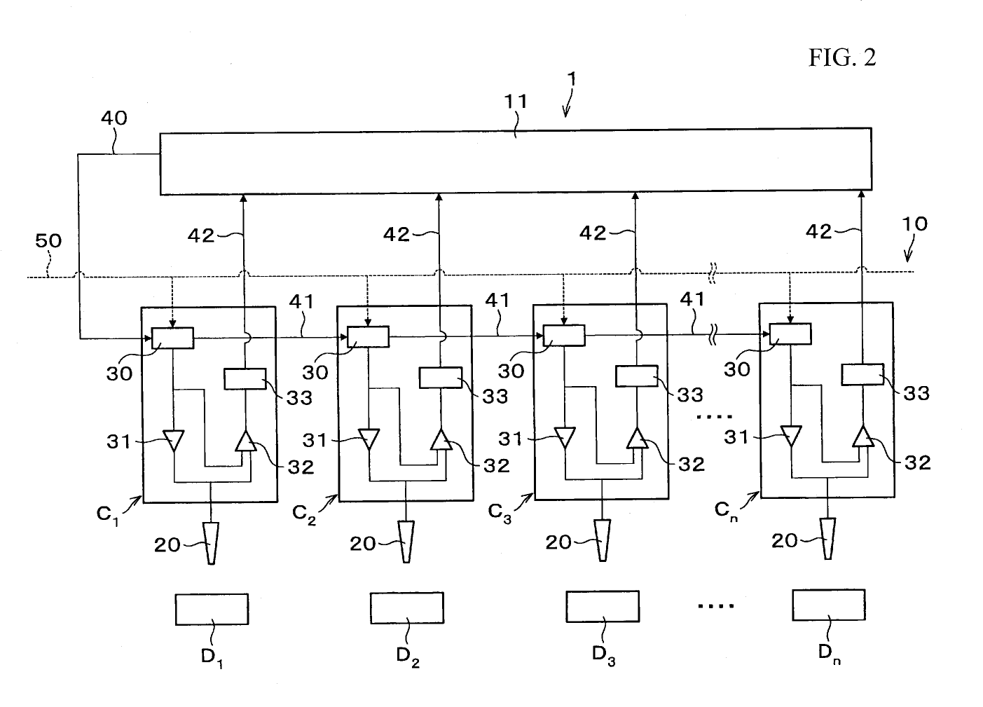

As illustrated in FIG. 2, the inspection cell (C) includes a test pattern memory 30, a driver 31, a comparator 32, and a test result memory 33. The test pattern memory 30 temporarily stores a test pattern transmitted from the tester 11. As will be described below, the test pattern memory 30 of the first inspection cell (C₁) is the only test pattern memory 30 that receives the test pattern from the tester 11. The test pattern (including an expected value corresponding to the test pattern) stored in the test pattern memory 30 is transmitted to the driver 31 and the comparator 32. The driver 31 transmits an inspection signal to the device (D) through the probe 20 according to the test pattern from the test pattern memory 30. The comparator 32 compares an output signal from the device (D) with the expected value corresponding to the test pattern from the test pattern memory 30 to obtain a test result, namely, “Pass” or “Fail.” The test result obtained by the comparator 32 is transmitted to the test result memory 33. The test result memory 33 temporarily stores the test result from the comparator 32.

The inspection signal from the driver 31 is output at high impedance. For this reason, in the present embodiment, a switch that switches between the driver 31 and the comparator 32 is not provided. However, the switch may be naturally provided between the driver 31 and the probe 20 and between the comparator 32 and the probe 20.

A wiring 40 for transmitting the test pattern (including the expected value corresponding to the test pattern) is provided between the tester 11 and the test pattern memory 30 of the first inspection cell (C₁). Further, a test-pattern wiring 41 for transmitting the test pattern is provided between the neighboring inspection cells (C, C). The test-pattern wiring 41 connects the test pattern memories 30 and 30 of the neighboring inspection cells (C, C). Here, the neighboring inspection cells (C, C) indicate the inspection cell (C) on an upstream side and the inspection cell (C) on a downstream side in inspection order of the devices (D), for example, the first inspection cell (C₁) and the second inspection cell (C₂), or the second inspection cell (C₂) and the third inspection cell (C₃). Accordingly, the neighboring inspection cells (C, C) are not limited to the inspection cells (C, C) that are arranged physically adjacent to each other in a planar view. The test pattern is transmitted to the test pattern memory 30 of the first inspection cell (C₁) on the furthermost upstream side from the tester 11, and then the test pattern is sequentially transmitted to the test pattern memory 30 of the n-th inspection cell (Cₙ) on the furthermost downstream side from the test pattern memory 30 of the first inspection cell (C₁).

Wirings 42 for transmitting the test results are respectively provided between the tester 11 and the test result memories 33 of the inspection cells (C). The test results stored in the test result memories 33 of the inspection cells (C) are individually transmitted to the tester 11 through the wirings 42.

A clock wiring 50 for transmitting a clock signal is connected to the test pattern memories 30 of the inspection cells (C). The clock wiring 50 is connected to a non-illustrated clock signal generating unit. In the test pattern memory 30, the test pattern stored in the test pattern memory 30 is rewritten in synchronization with the clock signal transmitted from the clock wiring 50.

The control unit 12 illustrated in FIG. 1 is, for example, a computer, and has a program storage unit (not illustrated). A program that controls transmission and reception of signals between the inspection apparatus 10 and the tester 11 and controls the inspection of the multiple devices (D) is stored in the program storage unit. The program may be recorded in, for example, a computer-readable hard disc (HD), a flexible disc (FD), a compact disc (CD), a magneto-optical disc (MO), or a computer-readable storage medium such as a memory card, and then be installed in the control unit 12 from such a storage medium.

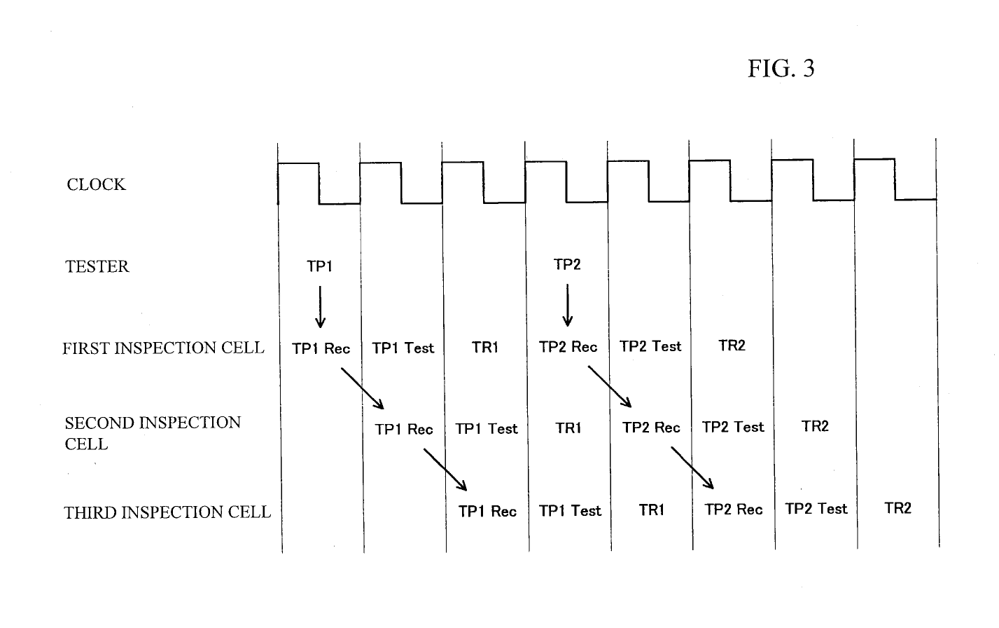

The inspection system 1 according to the present embodiment has a structure as described above. Next, a method for inspecting the multiple devices (D) by the inspection system 1 will be described. FIG. 3 is an explanatory diagram illustrating timings for inspecting the multiple devices (D) in the inspection system 1. In FIG. 3, an irregularity of a clock represents pulses of a clock signal. “TP” is an abbreviation for test pattern. “TR” is an abbreviation for test result. Further, “1” in “TP1” and “TR1” represents a first inspection, and “2” in “TP2” and “TR2” represents a second inspection. In FIG. 3, to simplify the illustration, it has been described that the first device (D₁) to the third device (D₃) are sequentially inspected by the first inspection cell (C₁) to the third inspection cell (C₃). However, the first device (D₁) to the n-th device (Dₙ) are actually inspected in sequence by the first inspection cell (C₁) to the n-th inspection cell (Cₙ).

Firstly, in the inspection system 1, the wafer (W) is moved in a horizontal direction, and the wafer (W) is disposed to face the inspection apparatus 10. That is, the devices (D) on the wafer (W) and the inspection cells (C) of the inspection apparatus 10 are disposed to face each other. Subsequently, the wafer (W) is moved in a vertical direction, and the probes 20 of the inspection apparatus 10 are brought to come in contact with the electrodes of the respective devices (D) on the wafer (W).

Thereafter, the test pattern is transmitted to the test pattern memory 30 of the first inspection cell (C₁) from the tester 11, and the test pattern is temporarily stored in the test pattern memory 30. In the first inspection cell (C₁), the first device (D₁) is inspected in synchronization with the clock signal transmitted to the test pattern memory 30.

In the first inspection cell (C₁), the test pattern (including the expected value corresponding to the test pattern) stored in the test pattern memory 30 is transmitted to the driver 31 and the comparator 32 in synchronization with the clock signal. In the test pattern memory 30, the test pattern is rewritten in synchronization with the clock signal. In the driver 31, the inspection signal is transmitted to the first device (D₁) through the probe 20 according to the test pattern from the test pattern memory 30. The output signal is transmitted to the comparator 32 from the first device (D₁) on the basis of the inspection signal. In the comparator 32, the output signal from the first device (D₁) is compared with the expected value corresponding to the test pattern from the test pattern memory 30 to obtain the test result. The test result obtained by the comparator 32 is transmitted to the test result memory 33. The test result memory 33 temporarily stores the test result from the comparator 32. The test result stored in the test result memory 33 is transmitted to the tester 11. By doing this, the first device (D₁) is inspected by the first inspection cell (C₁).

In parallel with the inspection of the first device (D₁), that is, in synchronization with the clock signal, the test pattern is transmitted to the test pattern memory 30 of the second inspection cell (C₂) from the test pattern memory 30 of the first inspection cell (C₁). The test pattern is temporarily stored in the test pattern memory 30 of the second inspection cell (C₂). In the second inspection cell (C₂), the second device (D₂) is inspected according to the test pattern of the test pattern memory 30. The inspection of the second device (D₂) is performed in the same manner as that of the first device (D₁) described above, and thus its description is not presented.

In this way, the test pattern is sequentially transmitted to the test pattern memory 30 of the n-th inspection cell (Cₙ) from the test pattern memory 30 of the first inspection cell (C₁). In each inspection cell (C), the device (D) is inspected according to the test pattern stored in the test pattern memory 30 of the inspection cell (C). By so setting, the first device (D₁) to the n-th device (Dₙ) are sequentially inspected by the inspection system 1.

In each inspection cell (C), each device (D) is inspected multiple times according to, for example, multiple test patterns. In the example of FIG. 3, although it has been illustrated that the device (D) is inspected twice by the inspection cell (C), any number of inspections may be conducted on the device (D).

According to the aforementioned embodiment, since the inspection cell (C) includes the test pattern memory 30, the driver 31, the comparator 32, and the test result memory 33, the inspection cell (C) may be disposed adjacent to the device (D) to inspect the device (D). Accordingly, distances are decreased at which the signals are transmitted between the driver 31 of the inspection cell (C) and the device (D) and between the comparator 32 and the device (D). When the transmission distances are decreased in this way, rounding of a signal waveform (a rising edge and a falling edge) is suppressed and the signals are transmitted with excellent reproduction, thus allowing transmission frequencies to be increased. Although the response speed of the device (D) determines the transmission frequencies of the signals transmitted and received between the driver 31 of the inspection cell (C) and the device (D) as well as between the comparator 32 and the device, according to the present embodiment, it is easier to design an inspection system having high frequency.

Since the test-pattern wiring 41 is provided between the inspection cells (C, C), the test pattern is sequentially transmitted to the test pattern memory 30 of the n-th inspection cell (Cₙ) from the test pattern memory 30 of the first inspection cell (C₁). That is, when the test pattern is transmitted to the test pattern memory 30 of the first inspection cell (C₁) on the furthermost upstream side from the tester 11, the first device (D₁) to the n-th device (Dₙ) can be sequentially inspected. Accordingly, unlike the related art, since it is not necessary for the signals to be individually transmitted to the devices from the tester, lengths of wirings for transmitting the signals do not vary. Therefore, the inspection accuracy of the devices (D) is improved.

In this way, since the test pattern can be sequentially transmitted to the test pattern memories 30 of the inspection cells (C), the test pattern is sequentially rewritten in the test pattern memories 30. For this reason, even when the devices (D) are inspected using the multiple test patterns, the test pattern memory 30 may store only the test pattern used in the corresponding inspection cell (C). Accordingly, the devices (D) are inspected according to the multiple test patterns using a simple structure. Further, in this case, since the inspection cell (C) can have simple structures, the inspection cell (C) can be disposed adjacent to the device (D). Therefore, the simple structure of the inspection cell is especially useful when a number of devices (D) are formed on the wafer (W).

Controlling the test pattern from the tester 11 is achieved only by controlling the test pattern for the first inspection cell (C₁) positioned furthermost upstream side. Thus, the devices (D) are inspected under simpler control than those in the related art. Furthermore, the inspection speed of the devices (D) is further improved under such simpler control.

In the test pattern memory 30 of the inspection cell (C), since the test pattern is rewritten in synchronization with the clock signal, the device (D) is inspected at an appropriate timing.

In the aforementioned embodiment, in the inspection cell (C), the rewriting of the test pattern in the test pattern memory 30 and the transmitting of the test result to the tester 11 from the test result memory 33 are performed in synchronization with the clock signal transmitted from the clock wiring 50, for example. However, the rewriting of the test pattern and the transmitting of the test result may be performed at different timings. For example, when a cycle of the clock signal and a test speed in the inspection cell (C) are different, the test pattern memory 30 may rewrite the test pattern in synchronization with the clock signal, and the test result memory 33 may transmit the test result to the tester 11 in synchronization with the test speed. Specifically, the test pattern in the test pattern memory 30 may be rewritten at, for example, the rising edge of the clock signal, and the clock signal may be allowed to fall at, for example, the timing matched with the test speed to transmit the test result to the tester 11 from the test result memory 33. In such a case, the inspection cell (C) may include a cache capable of absorbing the difference between the cycle of the clock signal and the test speed.

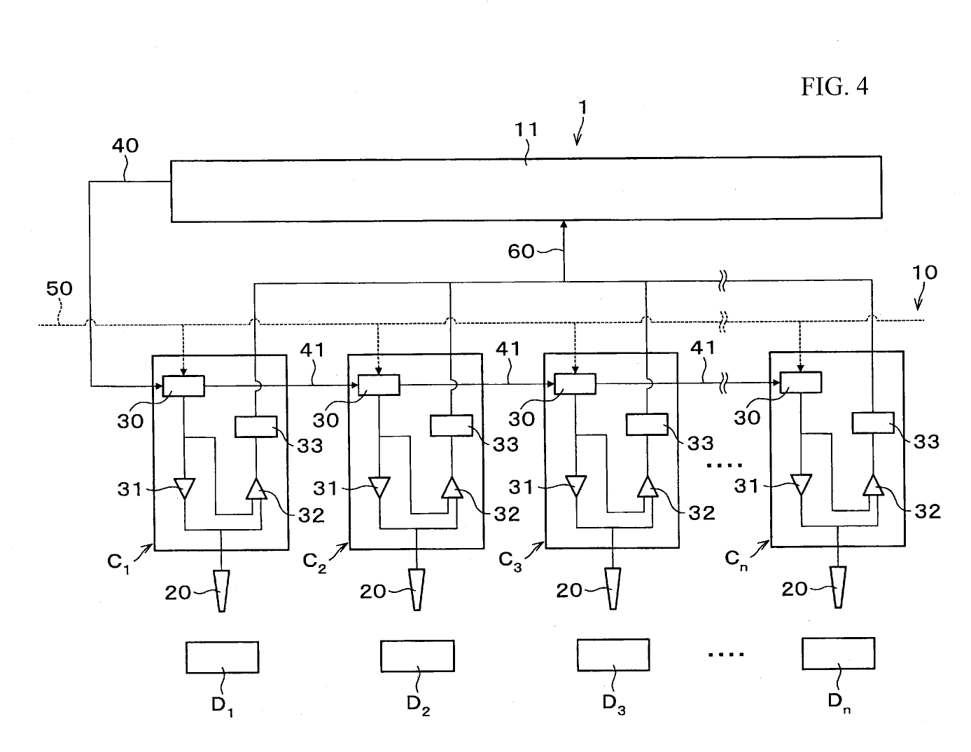

In the aforementioned embodiment, although the tester 11 and the test result memories 33 of the inspection cells (C) are set to be connected to each other through separate wiring 42, the tester 11 and the test result memories 33 may be connected to each other through one wiring 60 as illustrated in FIG. 4. The test results are sequentially transmitted to the tester 11 from the test result memories 33 of the first inspection cell (C₁) to the n-th inspection cell (Cₙ). In such a case, since it is not necessary to provide multiple wirings for outputting the test results between the tester 11 and the inspection apparatus 10, the structure of the inspection system 1 is simplified. The wiring 40 for connecting the tester 11 and the test pattern memory 30 and the wiring 60 for connecting the tester 11 and the test result memories 33 may be provided as one wiring.

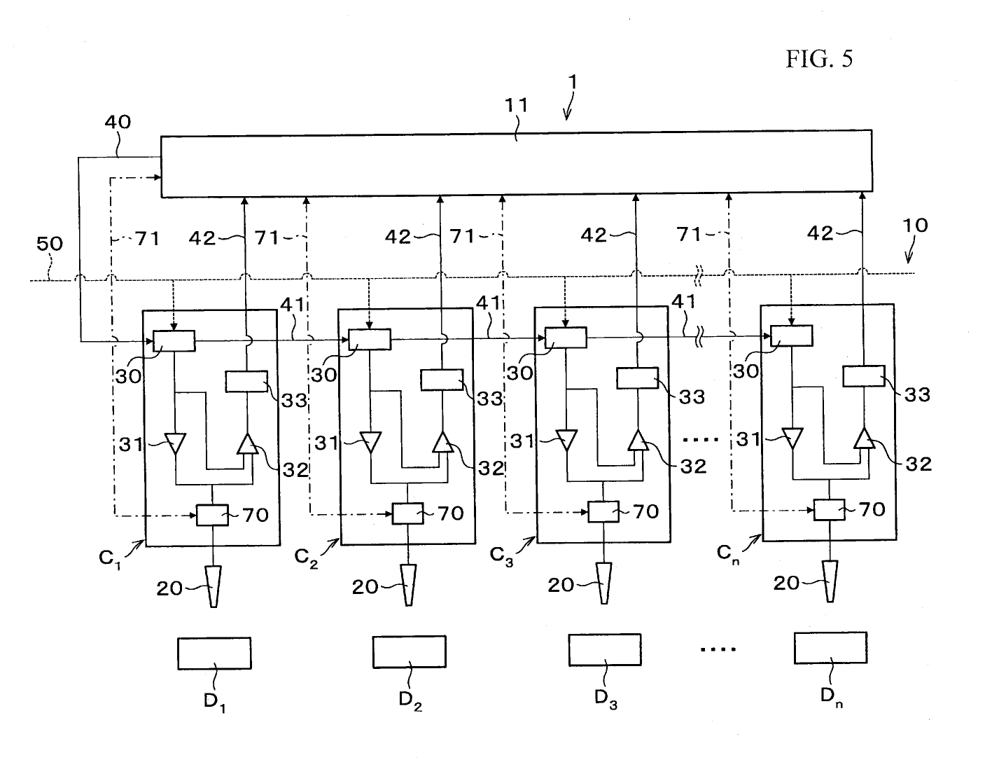

The inspection system 1 of the aforementioned embodiment is set to perform the inspection of the dynamic characteristics of the devices (D), for example, the function test. Alternatively, the inspection system 1 may be set to perform static inspection of the devices (D), for example, a DC parametric test for inspecting voltages and currents at the time of the operations of the devices (D). In order to perform the DC parametric test of the devices (D), each of the inspection cells (C) includes a switch 70 as illustrated in FIG. 5. A DC-parametric test wiring 71 that transmits an inspection signal for performing the DC parametric test from the tester 11 to the device (D) and transmits an output signal (a test result) from the device (D) to the tester 11 is provided between the switch 70 and the tester 11. The switch 70 can switch between the inspection signal transmitted from the driver 31 and the output signal transmitted to the comparator 32 for performing the function test of the device (D) and the signals for performing the DC parametric test of the device (D).

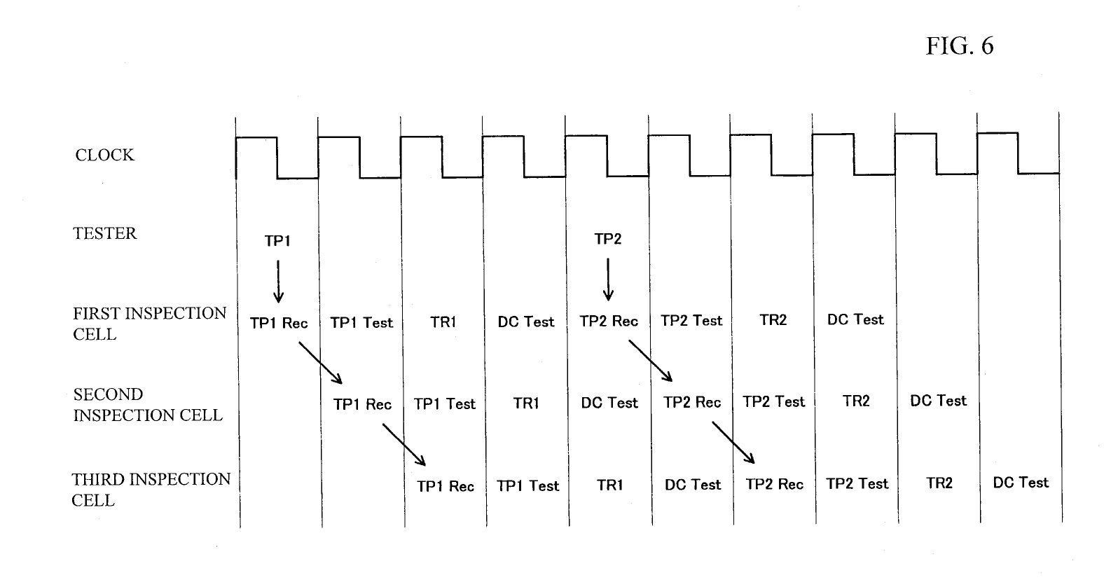

In this case, the inspection system 1 inspects the devices (D) at, for example, timings illustrated in FIG. 6. That is, in each of the inspection cells (C), the function test of the device (D) is first performed. The function test is performed in the same manner as that in the aforementioned embodiment, and thus the description thereof is omitted here. Thereafter, the switch 70 is switched to the DC-parametric test wiring 71, and the inspection signal for the DC parametric test is transmitted to the device (D) from the tester 11. On the basis of the inspection signal, the output signal (the test result) is transmitted to the tester 11 from the device (D). Accordingly, the DC parametric test of the device (D) is performed.

Similar to the aforementioned embodiment, the test pattern is sequentially transmitted from the test pattern memory 30 of the first inspection cell (C₁) to the test pattern memory 30 of the n-th inspection cell (Cₙ). The function test and the DC parametric test are sequentially performed from the first device (D₁) to the n-th device (Dₙ).

According to the present embodiment, by sequentially transmitting the test pattern from the first inspection cell (C₁) to the n-th inspection cell (Cₙ), the function test requiring at-speed testing is performed appropriately and the DC parametric test is performed by switching the switch 70. In this way, both the function test and the DC parametric test are performed by one inspection system 1 and the devices (D) are inspected efficiently.

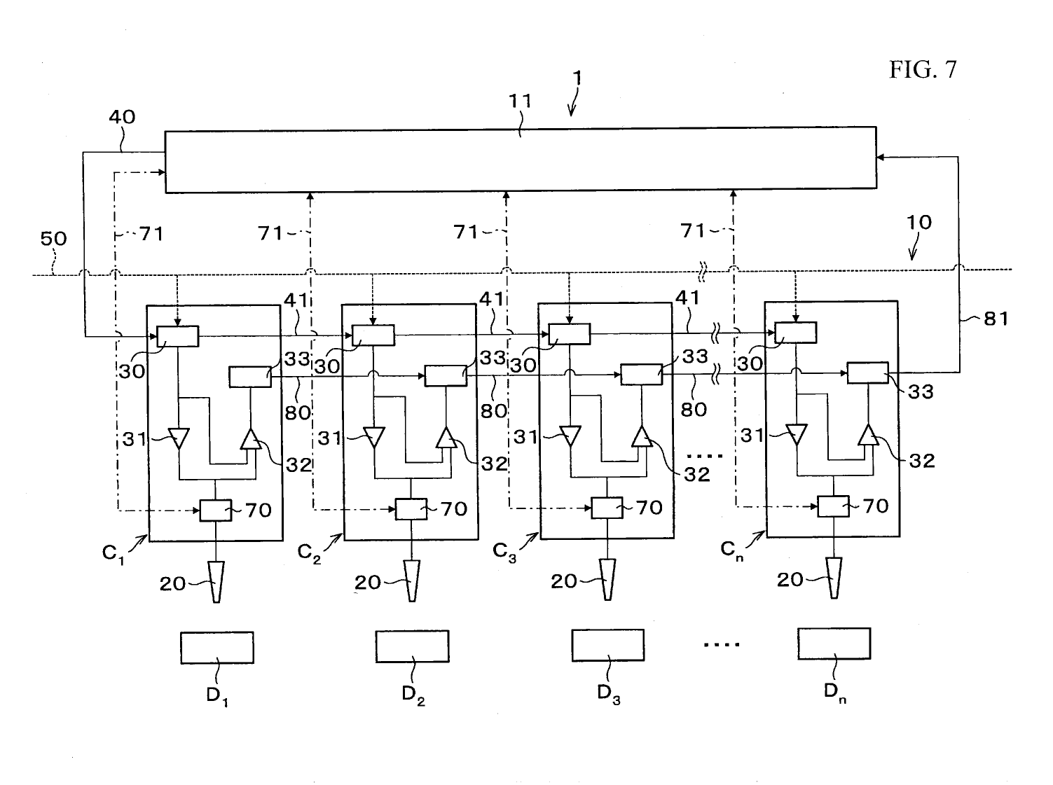

In the inspection system 1 of the aforementioned embodiment, a test-result wiring 80 for transmitting the test result may be provided between the neighboring inspection cells (C, C) as illustrated in FIG. 7. The test-result wiring 80 connects the test result memories (33, 33) of the neighboring inspection cells (C, C). Here, the neighboring inspection cells (C, C) indicate the inspection cell (C) on the upstream side and the inspection cell (C) on the downstream side positioned in the order that the devices (D) are inspected as stated above. Further, a wiring 81 for transmitting the test result is provided between the tester 11 and the test result memory 33 of the n-th inspection cell (Cₙ).

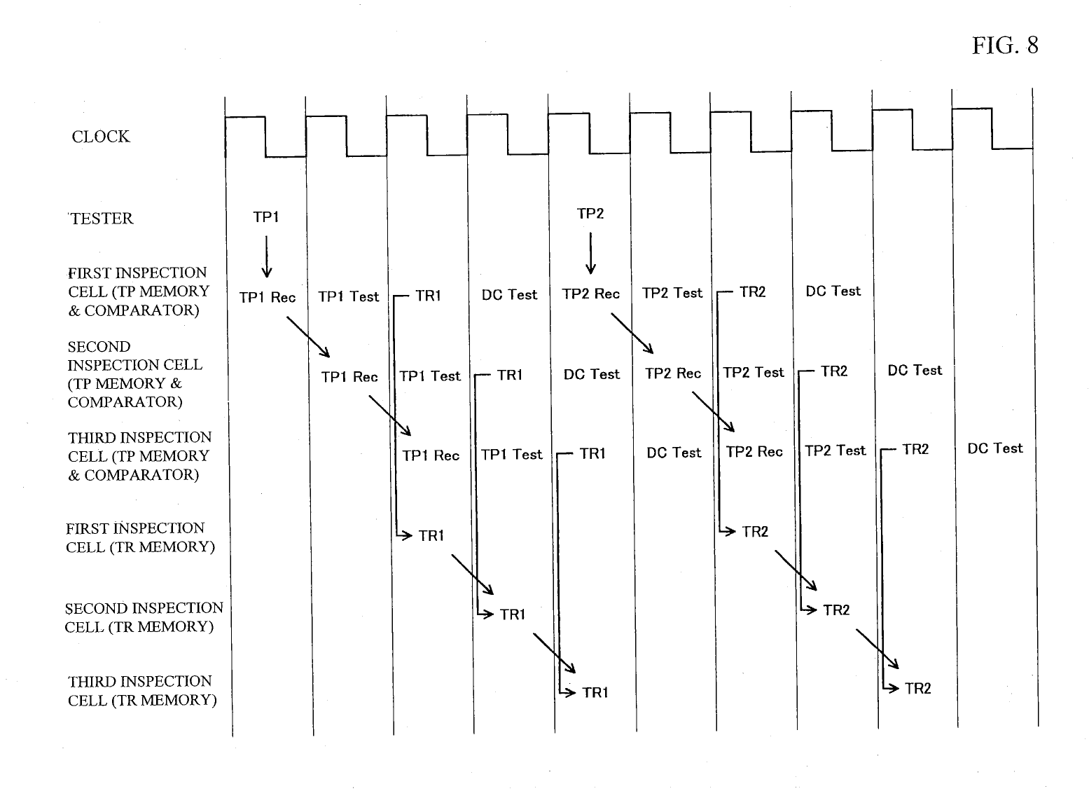

In this case, in the inspection system 1, the devices (D) are inspected at, for example, timings illustrated in FIG. 8. That is, the function test and DC parametric test of the device (D) are performed in each inspection cell (C). The function test and the DC parametric test of the devices (D) are performed in the same manner as those in the above-described embodiment, and thus their descriptions are omitted here. Now, after the function test is conducted in the inspection cell (C), a method for transmitting the test result stored in the test result memory 33 of the inspection cell (C) to the tester 11 will be described.

The test result for the first device (D₁) stored in the test result memory 33 of the first inspection cell (C₁) is transmitted to the test result memory 33 of the second inspection cell (C₂). At this time, the second inspection cell (C₂) ends the inspection for the second device (D₂) and stores the test result for the second device (D₂) in the test result memory 33. In the test result memory 33 of the second inspection cell (C₂), when both the test result of the first device (D₁) and the test result of the second device (D₂) are “Pass,” the test result is “Pass.” On the other hand, when at least one of the test result of the first device (D₁) and the test result of the second device (D₂) is “Fail,” the test result is “Fail.” The test result is sequentially transmitted from the test result memory 33 of the first inspection cell (C₁) to the test result memory 33 of the n-th inspection cell (Cₙ).

By so setting, in the inspection system 1 of the present embodiment, one test result is obtained from all the multiple devices (D). That is, when the test result of the multiple devices (D) are all “Pass,” “Pass” is stored as the test result in the test result memory 33 of the n-th inspection cell (Cₙ). On the other hand, when any one of the test results of the multiple devices (D) is “Fail,” “Fail” is stored as the test result. The test result stored in the test result memory 33 of the n-th inspection cell (Cₙ) is transmitted to the tester 11 through the wiring 81.

According to the present embodiment, the test result from the inspection apparatus 10 is transmitted through one wiring 81. Accordingly, unlike the related art, since it is not necessary to individually transmit the signals to the tester from the devices, the lengths of wiring for transmitting the signals do not vary. For this reason, the inspection accuracy of the devices (D) is further improved.

Controlling the test result to the tester 11 is achieved only by controlling the test result from the n-th inspection cell (Cₙ) positioned furthermost downstream. Thus, the devices (D) are inspected under simpler control than those in the related art. Furthermore, the inspection speed of the devices (D) is further improved under the simpler control.

In the aforementioned embodiment as well, the rewriting of the test pattern in the test pattern memory 30 of the inspection cell (C), the transmitting of the test result to the inspection cell (C) on the downstream side from the inspection cell (C) on the upstream side, and the transmitting of the test result to the tester 11 from the n-th inspection cell (Cₙ) may be performed in synchronization with the clock signal transmitted from the clock wiring 50, or may be performed at different timings. That is, the test pattern memory 30 rewrites the test pattern in synchronization with the clock signal, for example. Meanwhile, the transmitting of the test result to the test result memory 33 of the inspection cell (C) on the downstream side from the test result memory 33 of the inspection cell (C) on the upstream side and the transmitting of the test result to the tester 11 from the test result memory 33 of the n-th inspection cell (Cₙ) on the most downstream side are performed in synchronization with the test speed.

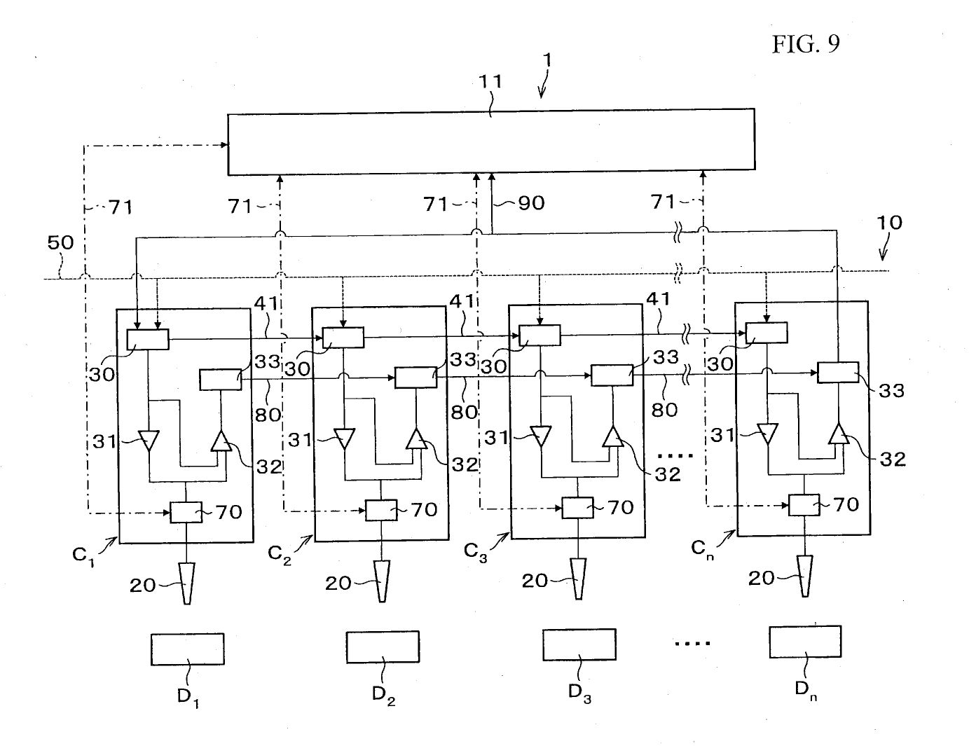

In the aforementioned embodiment, the tester 11 and the inspection apparatus 10 are set to be connected to each other through separate wirings 40 and 81. However, they may be connected to each other through one wiring 90 as illustrated in FIG. 9. In such a case, the test pattern to the first inspection cell (C₁) from the tester 11 and the test result to the tester 11 from the n-th inspection cell (Cₙ) are transmitted using the one wiring 90. In this case, since one of the two wirings is not provided, the structure of the inspection system 1 is simplified.

In the aforementioned embodiment, the test pattern and the expected value corresponding to the test pattern are sequentially transmitted to the test pattern memory 30 of the first inspection cell (C₁) from the tester 11. However, the technology described in the present application is also applicable to cases where only the test pattern is transmitted to the test pattern memory 30 of the first inspection cell (C₁) from the tester 11.

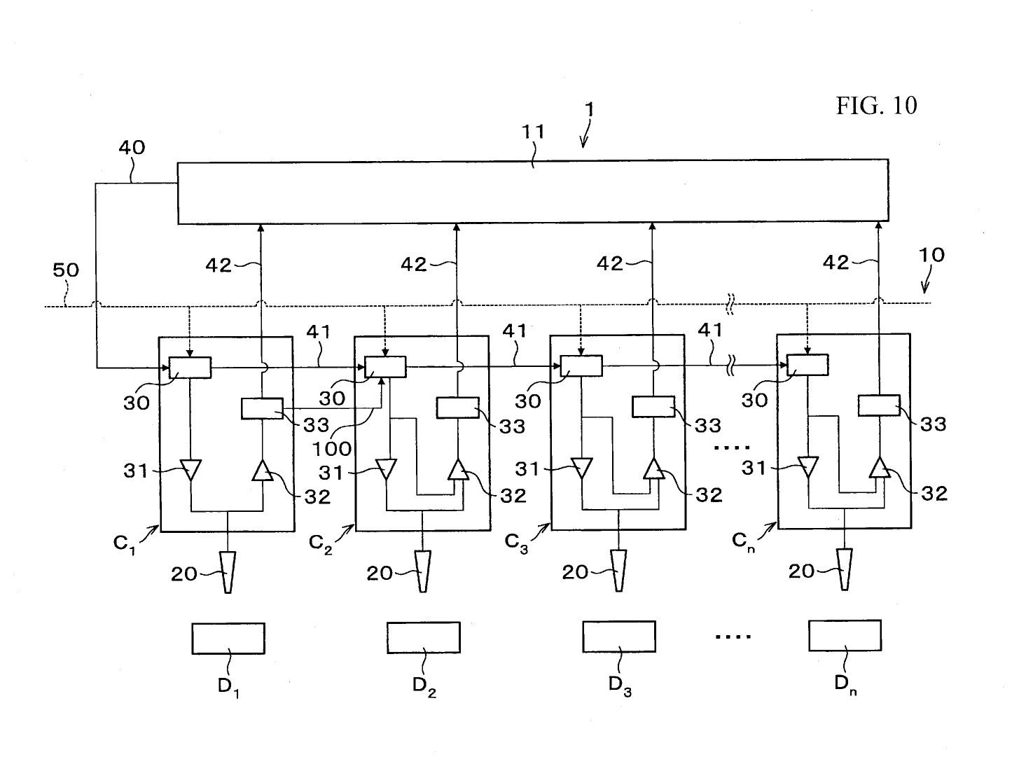

In such a case, as illustrated in FIG. 10, the test result memory 33 of the first inspection cell (C₁) and the test pattern memory 30 of the second inspection cell (C₂) are connected to each other by a wiring 100, for example.

When the multiple devices (D) are inspected, first, in the first inspection cell (C₁), the inspection signal is transmitted to the first device (D₁) according to the test pattern transmitted from the tester 11, and the output signal from the first device (D₁) is output to the test result memory 33. At this time, since the expected value corresponding to the test pattern is not transmitted from the tester 11, the comparator 32 does not compare the output signal from the first device (D₁) with the expected value corresponding to the test pattern as in the above-described embodiment. The output signal from the first device (D₁) becomes the expected value corresponding to the test pattern in the inspection cells (C₂) to (Cₙ) on the downstream side of the first inspection cell (C₁).

Next, the test pattern is transmitted from the test pattern memory 30 of the first inspection cell (C₁) to the test pattern memory 30 of the second inspection cell (C₂), and the output signal from the first device (D₁) is transmitted from the test result memory 33 of the first inspection cell (C₁).

In the second inspection cell (C₂), the test pattern stored in the test pattern memory 30 and the output signal from the first device (D₁) are transmitted to the driver 31 and the comparator 32. In the driver 31, the inspection signal is transmitted to the second device (D₂) through the probe 20 according to the test pattern of the test pattern memory 30. Based on the inspection signal, the output signal is transmitted to the comparator 32 from the second device (D₂). In the comparator 32, the output signal from the second device (D₂) and the output signal from the first device (D₁) from the test pattern memory 30 are compared with each other, and a test result indicating whether or not the output signals are equal to each other is obtained. The test result obtained by the comparator 32 is transmitted to the test result memory 33. The test result memory 33 temporarily stores the test result from the comparator 32. The test result stored in the test result memory 33 is transmitted to the tester 11. Accordingly, the second device (D₂) is inspected by the second inspection cell (C₂).

Thereafter, the test pattern and the output signal from the first device (D₁) are sequentially transmitted from the test pattern memory 30 of the second inspection cell (C₂) to the test pattern memory 30 of the n-th inspection cell (Cₙ). In each of the inspection cells (C), the device (D) is inspected according to the test pattern stored in the test pattern memory 30 of the inspection cell (C) and the output signal from the first device (D₁). In this way, the second device (D₂) to the n-th device (Dₙ) are sequentially inspected by the inspection system 1.

In the aforementioned embodiments, the output signal from the first device (D₁) is regarded as the expected value corresponding to the test pattern, and the second device (D₂) to the n-th device (Dₙ) are sequentially inspected. That is, a comparison inspection is performed to determine whether or not the output signals from the second device (D₂) to the n-th device (Dₙ) are equal to the output signal from the first device (D₁). By doing so, even when the expected value corresponding to the test pattern is not previously obtained, the comparison inspection of the first device (D₁) to the n-th device (Dₙ) is performed. In other words, when a random signal as the test pattern from the tester 11 is transmitted to the first inspection cell (C₁), the comparison inspection of the present embodiment can be performed, so that a faulty device (D) is detected. Accordingly, the first device (D₁) to the n-th device (Dₙ) are inspected by a simpler method.

In a mass production stage of products, the ratio of defective devices (D) is generally low. Accordingly, the comparison inspection of the first device (D₁) to the n-th device (Dₙ) as in the present embodiment is effective in detecting a faulty device (D).

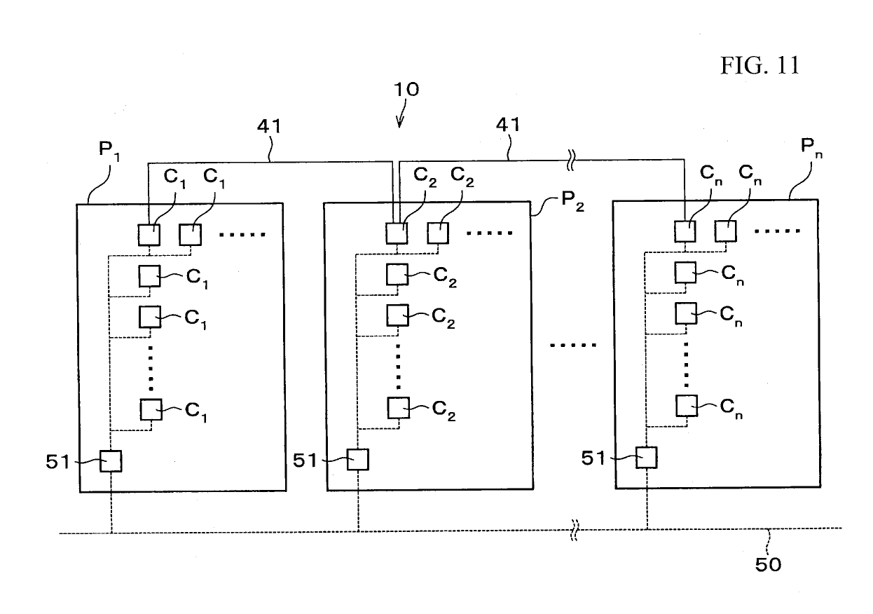

In the inspection apparatus 10 of the aforementioned embodiment, a series of inspection cells (C) of the first inspection cell (C₁) to the n-th inspection cell (Cₙ) may be provided as multiple sets, for example, m sets (where m is an integer of 2 or greater) as illustrated in FIG. 11. That is, multiple first inspection cells (C₁) may be provided, and, for example, m sets of first inspection cells (C₁) may be provided. The multiple first inspection cells (C₁) form a first inspection chip (P₁). Similarly, multiple n-th inspection cells (Cₙ) form an n-th inspection chip (Pₙ). The inspection chips (P) are respectively formed so as to correspond to chips including the multiple devices (D) on the wafer (W).

A driver 51 for transmitting, for example, the clock signal from the clock wiring 50 to the multiple inspection cells (C) in the inspection chip (P) is provided at each of the inspection chips (P). The driver 51 is disposed so that wirings from the driver 51 to the inspection cells (C) are set to have the same length. In FIG. 11, for the sake of convenience in illustration, the wiring lengths are different. As a result, the same wiring lengths cause the pulses of the clock signals transmitted to the multiple inspection cells (C) in one inspection chip (P) to be set at the same timing. That is, in one inspection chip (P), the devices (D) are simultaneously inspected by the multiple inspection cells (C). A method for setting the pulses of the clock signals at the same timing is not limited to the method for setting the wiring lengths to be the same as in the embodiment. For example, a memory that temporarily stores the clock signals may be provided in the inspection chip (P).

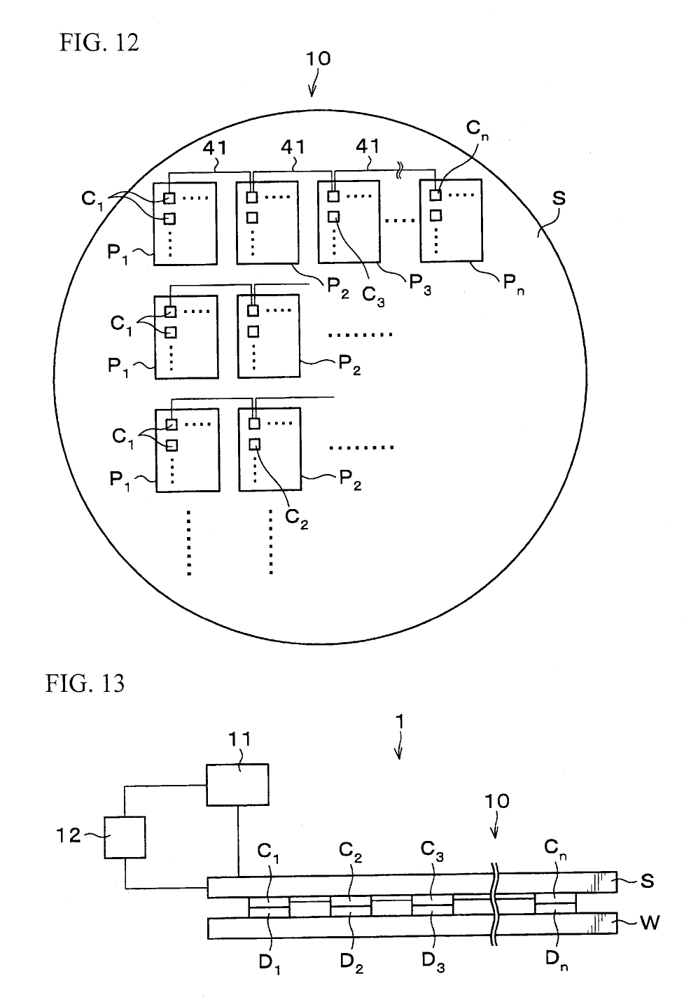

Multiple first inspection chips (P₁) to the n-th inspection chips (Pₙ) may be provided on the support substrate (S) as illustrated in FIG. 12.

As in the aforementioned embodiment, the inspection apparatus 10 of the technology disclosed in the present application is also applicable to cases where target objects of various units such as device units or chip units are inspected.

In the aforementioned embodiment, the multiple inspection cells (C) of the inspection apparatus 10 and the multiple devices (D) on the wafer (W) are set to be in one-to-one correspondence, and the inspection system 1 inspects the multiple devices (D) on the wafer (W). However, that is not the only option for the inspection method of the technology disclosed in the present application. For example, the number of the inspection cells (C) of the inspection apparatus 10 may be one fourth the number of the devices (D) on the wafer (W), and the inspection apparatus 10 may move one fourth of the surface at one time on the wafer (W) to inspect the devices. Alternatively, for example, the number of the inspection cells (C) of the inspection apparatus 10 may be the same number of the devices (D) in one chip positioned on the wafer (W), and the inspection apparatus may move chip by chip to inspect the devices.

In the aforementioned embodiment, the transmitting of the test pattern to the test pattern memory 30 of the first inspection cell (C₁) from the tester 11 is set to perform through the wiring 40. However, the transmitting may be performed wirelessly including light transmission. Moreover, the transmitting of the test result to the tester 11 from the test result memory 33 of the inspection cell (C) may be also performed wirelessly including light transmission. Since the test pattern and the test result can be appropriately transmitted wirelessly, the same effect is exhibited as that in the above-described embodiment.

Only data of either the test pattern or the test results may be transmitted wirelessly. For example, the transmitting of the test result to the tester 11 from the test result memory 33 of the inspection cell (C) may be performed wirelessly, and the transmitting of the test pattern to the test pattern memory 30 of the first inspection cell (C₁) from the tester 11 may be performed through the wiring 40. In such a case, since the test result is digital data, it is easier to perform wireless transmission of the test result to the tester 11 from the test result memory 33 of the inspection cell (C). In addition, when transmission of the test result is performed wirelessly, the wiring 42 can be omitted. For this reason, the wirings between the tester 11 and the inspection cells (C) are markedly simplified.

In the aforementioned embodiment, although the tester 11 and the control unit 12 are separately provided, the control unit 12 may have a function of the tester 11. That is, the control unit 12 may transmit the test pattern to the inspection apparatus 10 and receive the test result from the inspection apparatus 10. The control unit 12 is, for example, a computer, and is capable of performing such functions. In this case, since the tester 11 can be omitted, the inspection system 1 is further simplified.

Although the inspection apparatus 10 of the aforementioned embodiment has included the probes 20, it is an option to omit the probes 20 as illustrated in FIG. 13. In such a case, the inspection cells (C) come in contact with the electrodes of the devices (D) to inspect the devices (D), for example. In FIG. 13, to simplify the illustration of the technology, the ratio of the thickness of the inspection cells (C) to that of the support substrate (S) and the ratio of the thickness of the devices (D) to that of the support substrate (S) do not correspond to actual ratios. That is, the actual thicknesses of the inspection cells (C) and the devices (D) are extremely thin. Thus, the wafer (W) and the support substrate (S) may be laminated to bring the inspection cells (C) in contact with the electrodes of the devices (D). In any case, the devices (D) can be inspected by electrically connecting the inspection cells (C) and the devices (D).

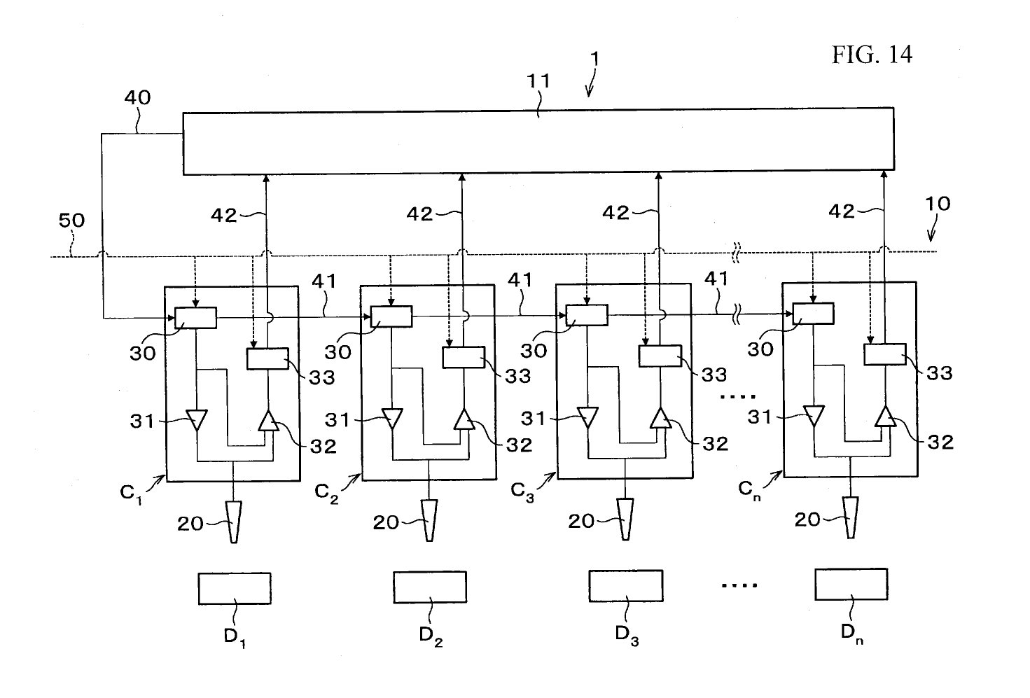

In the inspection system 1 of the aforementioned embodiment, the clock wiring 50 may be connected to the test result memories 33 of the inspection cells (C) as illustrated in FIG. 14. In this case, by using the rising edge of the clock signal, the test pattern in the test pattern memory 30 is rewritten, and the driver 31 is driven to transmit the inspection signal to the device (D). Further, by using the falling edge of the clock signal, the comparator 32 is driven to compare the output signal from the device (D) with the expected value corresponding to the test pattern from the test pattern memory 30, and thus the test result is obtained. In actuality, since a setup time is needed for the device (D), the rising edge and falling edge of the clock signal after several clock signals may be used for such purposes. Since the test pattern and the test result are also appropriately transmitted, the same effect as that of the aforementioned embodiment is exhibited.

In the aforementioned embodiment, the test result memory 33 of the inspection cell (C) may be set to have a function for determining the test result along with a function of overwriting and saving the test result. In this case, one test result obtained through multiple inspections is stored in the test result memory 33. Specifically, when even one test result is “Fail”, “Fail” is stored in the test result memory 33. Meanwhile, when all the test results are “Pass,” “Pass” is stored in the test result memory 33. After the inspection of the inspection cells (C) is finished, the test result memories 33 of the inspection cells (C) are all scanned to determine the quality of a chip. In this case, since it is not required to frequently transmit the test results to the tester 11 from the test result memories 33, the inspection is simplified.

When “Fail” is stored in the test result memory 33, an address of the faulty device (D) may be recorded in the test result memory 33. In such a case, the quality of the chip is determined and the address of the faulty device (D) is checked.

In the aforementioned embodiments, the inspection system 1 is set to inspect the devices (D) on a wafer (W). However, that is not the only target object to be inspected by the inspection system 1 of the technology disclosed in the present application. For example, when multiple target objects are inspected, the inspection system 1 of the technology disclosed in the present application can also be used for such inspection.

While the preferred embodiments of the technology disclosed in the present application have been described with reference to the accompanying drawings, the technology disclosed in the present application is not limited to the embodiments. It will be apparent to those skilled in the art that various modifications and variations can be made without departing from the spirit as defined by the appended claims, and it should be understood that the modifications and variations are encompassed within the technical scope of the technology disclosed in the present specification. The technology disclosed in the present application is not limited to the embodiments above, and may be embodied in a variety of other forms. The technology disclosed in the present application is applicable to cases where substrates other than the wafer, such as an FPD (Flat Panel Display) and a mask reticle for a photomask, are used.

In recent years, as high performance of a semiconductor device is required, the high integration of devices has been advanced. As a result, the number of devices is increased, and the number of probes, the number of drivers and the number of comparators are also increased.

In such a case, even though the comparators are disposed adjacent to the devices, the lengths of the wirings for connecting the tester and the probes do not vary. Accordingly, the inspection accuracy of the devices is degraded.

Furthermore, since the number of drivers is increased, when the inspection signals from the drivers are individually controlled, the control is complicated.

An inspection apparatus according to an embodiment of the present invention is capable of inspecting multiple target objects simply and appropriately. The inspection apparatus includes multiple inspection cells formed to correspond to the target objects. Each inspection cell includes a test pattern memory that temporarily stores a test pattern, a driver that transmits an inspection signal to the target object according to the test pattern, a comparator that compares an output signal from the target object with an expected value corresponding to the test pattern to obtain a test result, and a test result memory that temporarily stores the test result. Between the inspection cells, a test-pattern wiring is provided for transmitting the test pattern from the test pattern memory of the inspection cell on an upstream side to the test pattern memory of the inspection cell on a downstream side in the order that the target objects are inspected.

Since the inspection cell includes the test pattern memory, the driver, the comparator, and the test result memory, the inspection cell is disposed adjacent to the target object to inspect the target object, thus resulting in a reduction of distances for transmitting signals between the target object and the driver of the inspection cell and between the target object and the comparator. Therefore, the inspection accuracy of the target objects and the inspection speed are improved.

Since the test-pattern wiring is provided between the inspection cells, the test pattern stored in the test pattern memory of one inspection cell is sequentially transmitted to the test pattern memory of the inspection cell on a downstream side of the one inspection cell. That is, when the test pattern is transmitted to the test pattern memory of the inspection cell furthermost upstream from the outside (for example, a tester) of the inspection apparatus, the multiple target objects are inspected sequentially. Accordingly, unlike the related art, since it is not necessary to individually transmit signals to the target objects from the tester, the lengths of wirings for transmitting the signals do not vary. Therefore, the inspection accuracy of the target objects is improved.

In this way, since the test pattern is sequentially transmitted to the test pattern memories of the inspection cells, the test pattern is sequentially rewritten in the test pattern memories. For this reason, even when the target object is inspected using multiple test patterns, it is necessary for the test pattern memory to store only the test pattern used in the corresponding inspection cell. Accordingly, the target objects are inspected according to multiple test patterns using a simple structure. In this case, since the inspection cell has a simple structure, the inspection cell is disposed adjacent to the target object, so the simple structure of the inspection cell is especially useful when a number of target objects are formed.

Since control of the test pattern from the outside of the inspection apparatus is performed only for the test pattern for the inspection cell on the furthermost upstream side, the target objects are inspected under simpler control than in the related art. Furthermore, the inspection speed of the target objects under the easier control is further improved. As stated above, according to the technology disclosed in the present application, the multiple target objects are inspected simply and appropriately.

According to another embodiment of the present invention, an inspection system is provided which includes an inspection apparatus that inspects multiple target objects. The inspection apparatus includes multiple inspection cells formed to correspond to multiple target objects. Each inspection cell includes a test pattern memory that temporarily stores a test pattern, a driver that transmits an inspection signal to the target object according to the test pattern, a comparator that compares an output signal from the target object with an expected value corresponding to the test pattern to obtain a test result, and a test result memory that temporarily stores the test result. Between the inspection cells, a test-pattern wiring is provided for transmitting the test pattern from the test pattern memory of the inspection cell on an upstream side to the test pattern memory of the inspection cell on a downstream side in the order that the target objects are inspected. The inspection system includes a tester that transmits a test pattern to the test pattern memory and receives a test result from the test pattern memory and a control unit that controls inspection of the target objects in the inspection apparatus.

According to yet another embodiment of the present invention, an inspection method for inspecting multiple target objects is provided. Formed to correspond to the target objects are inspection cells, which include a test pattern memory that temporarily stores a test pattern, a driver that transmits an inspection signal to the target object according to the test pattern, a comparator that compares an output signal from the target object with an expected value corresponding to the test pattern to obtain a test result, and a test result memory that temporarily stores the test result. The multiple target objects are sequentially inspected by sequentially transmitting the test pattern stored in the test pattern memory of one inspection cell to the test pattern memory of the inspection cell on a downstream side of the one inspection cell and inspecting the target object in the inspection cell according to the transmitted test pattern.

According to the embodiments of the present invention, the multiple target objects are inspected simply and appropriately.

Obviously, numerous modifications and variations of the present invention are possible in light of the above teachings. It is therefore to be understood that within the scope of the appended claims, the invention may be practiced otherwise than as specifically described herein.

What is claimed is:

1. An inspection apparatus for inspecting target objects, comprising:
a plurality of inspection cells corresponding to target objects, respectively; and
a test-pattern wiring formed between the inspection cells,
wherein each of the inspection cell includes a test pattern memory device configured to temporarily store a test pattern, an inspection signal driver device configured to transmit an inspection signal to a respective one of the target objects based on the test pattern, a comparator device configured to compare an output signal from the respective one of the target objects with an expected value corresponding to the test pattern such that a test result is obtained, and a test result memory device configured to temporarily store the test result, and the test-pattern wiring is configured to transmit the test pattern to the test pattern memory device of each of the inspection cells from an upstream side to a downstream side in the order that the target objects are inspected.

2. The inspection apparatus according to claim 1, wherein the test pattern memory device is configured to rewrite the test pattern in synchronization with a clock signal.

3. The inspection apparatus according to claim 1, wherein the test pattern memory device is configured to rewrite the test pattern based on a rising edge of a clock signal, the driver device is configured to be driven based on the rising edge of the clock signal to transmit the inspection signal to the target object, and the comparator device is configured to be driven based on a falling edge of the clock signal to obtain the test result.

4. The inspection apparatus according to claim 1, wherein each of the inspection cells includes a switch device configured to switch between a signal for inspecting static characteristics of the respective one of the target objects and the inspection signal from the driver device and the output signal to the comparator device for inspecting dynamic characteristics of the respective one of the target objects.

5. The inspection apparatus according to claim 1, further comprising:
a test-result wiring formed between the inspection cells,
wherein the test-result wiring is configured to transmit the test result to the test result memory device of each of the inspection cells from the upstream side to the downstream side in the order that the target objects are inspected.

6. The inspection apparatus according to claim 1, wherein the output signal from an upstream inspection cell on the upstream side is the expected value for the test pattern in a downstream inspection cell on the downstream side relative to the upstream inspection cell on the upstream side sequentially in the order that the target objects are inspected.

7. The inspection apparatus according to claim 6, wherein the output signal from the most upstream inspection cell for the test pattern in a downstream inspection cell on the downstream side relative to the most upstream inspection cell on the upstream side sequentially in the order that at least three of the target objects are inspected.

8. The inspection apparatus according to claim 1, wherein the plurality of inspection cells connected through the test-pattern wiring is provided in a plurality of sets.

9. The inspection apparatus according to claim 1, wherein the test result memory device is configured to determine, overwrite and save the test result.

10. An inspection system for inspecting target objects, comprising:
an inspection apparatus configured to inspect a plurality of target objects;
a control device configured to control inspection of the target objects by the inspection apparatus; and
a tester device configured to transmit a test pattern to the inspection apparatus and receive a test result from the inspection apparatus,
wherein the inspection apparatus includes a plurality of inspection cells corresponding to the target objects, respectively, and a test-pattern wiring formed between the inspection cells, each of the inspection cells includes a test pattern memory device configured to temporarily store the test pattern, an inspection signal driver device configured to transmit an inspection signal to a respective one of the target objects based on the test pattern, a comparator device configured to compare an output signal from the respective one of the target objects with an expected value corresponding to the test pattern such that a test result is obtained, and a test result memory device configured to temporarily store the test result, the test-pattern wiring is configured to transmit the test pattern to the test pattern memory device of each of the inspection cells from an upstream side to a downstream side in the order that the target objects are inspected, and the tester device is configured to transmit the test pattern to the test pattern memory device and receive the test result from the test result memory device.

11. The inspection system according to claim 10, further comprising:
a first wiring connecting the tester device and the inspection apparatus; and
a second wiring connecting the tester device and the inspection apparatus,
wherein the first wiring is connected such that the test pattern is transmitted between the tester device and the inspection cells, and the second wiring is connected such that the test result is transmitted between the tester device and the inspection cells.

12. The inspection system according to claim 10, further comprising:
a wireless connection device configured to wirelessly connect the tester device and the inspection apparatus,
wherein the wireless connection device is configured to wirelessly transmit at least one of the test pattern and the test result between the tester device and the inspection cells.

13. An inspection method for inspecting target objects, comprising:
temporarily storing a test pattern in a test pattern memory device;
transmitting an inspection signal to a target object from an inspection signal driver device based on the test pattern;
comparing an output signal from the target object with an expected value corresponding to the test pattern by a comparator device such that a test result is obtained; and
temporarily storing the test result in a test result memory device,
wherein the test pattern memory device, the inspection signal driver device, the comparator device, and the test result memory device are formed in each of inspection cells corresponding to target objects, respectively, and the test pattern stored in the test pattern memory device of each of the inspection cells is sequentially transmitted to the test pattern memory device of another one of the inspection cells on a downstream side such that the inspection cells sequentially inspect the target objects based on the test pattern transmitted.

14. The inspection method according to claim 13, wherein the test pattern memory device rewrites the test pattern in synchronization with a clock signal.

15. The inspection method according to claim 13, wherein the test pattern memory device rewrites the test pattern on based on a rising edge of a clock signal, the inspection signal driver device is driven based on the rising edge of the clock signal to transmit an inspection signal to the target object, and the comparator device is driven based on a falling edge of the clock signal to obtain the test result.

16. The inspection method according to claim 13, wherein each of the inspection cells includes a switch device which switches between a signal for inspecting static characteristics of the target objects and the inspection signal from the driver device and the output signal to the comparator device for inspecting dynamic characteristics of the target objects such that both dynamic characteristics and static characteristics of the target objects are inspected by switching of the switch device.

17. The inspection method according to claim 13, wherein the test result stored in the test result memory device of one inspection cell of the plurality of inspection cells is sequentially transmitted to the test result memory device of another inspection cell on a downstream side such that one test result is obtained for the plurality of target objects.

18. The inspection method according to claim 13, wherein the output signal from an upstream inspection cell on an upstream side is the expected value for the test pattern in a downstream inspection cell on the downstream side relative to the upstream inspection cell on the upstream side sequentially in the order that the target objects are inspected.

19. The inspection method according to claim 18, wherein the output signal from the most upstream inspection cell for the test pattern in a downstream inspection cell on the downstream side relative to the most upstream inspection cell on the upstream side sequentially in the order that at least three of the target objects are inspected.

20. The inspection method according to claim 13, wherein the plurality of inspection cells connected through the test-pattern wiring is provided in a plurality of sets such that the plurality of inspection cells sequentially performs inspections of the target objects and the sets of pluralities of inspection cells simultaneously inspect the target objects.

21. The inspection method according to claim 13, wherein the test result memory device determines, overwrites and saves the test result.

22. The inspection method according to claim 13, wherein the test pattern is transmitted to the inspection cells from a tester device, the test result is transmitted to the tester device from the inspection cells, the test pattern is transmitted through one wiring between the tester device and the plurality of inspection cells, and the test result is transmitted through one wiring between the tester device and the inspection cells.

23. The inspection method according to claim 13, wherein at least one of the test pattern and the test result is wirelessly transmitted between the inspection cells and a tester device.
